(19) United States
(12) Patent Application Publication
(10) Pub. No.: US 2026/0332107 A1
(43) Pub. Date: Oct. 22, 2026

(54) Multi-Zone Preamplifier

(71) Applicant: McIntosh Laboratory, Inc., Framingham, MA (US)

(72) Inventors: Max Stephen McCarthy, Endwell, NY (US); Mark Brian Nazar, East Walpole, MA (US)

(21) Appl. No.: 19/180,396

(22) Filed: Apr. 16, 2025

(51) Int. Cl. H03F 3/183; H04R 3/12; H04S 3/00

(52) U.S. Cl. CPC H03F 3/183; H04R 3/12; H04S 3/008; H03F 2200/03; H04S 2400/01; H04S 2400/13

(57) ABSTRACT

Various aspects include audio pre-amplifiers for controlling zoned audio outputs, both in terms of switching and in controlling output characteristics of the signals. In some particular aspects, an audio pre-amplifier includes: a plurality of distinct inputs for receiving audio input signals; a plurality of distinct zone outputs for providing output signals according to zoned audio outputs; and at least one processor configured to control: switching the plurality of distinct inputs relative to the plurality of distinct zoned outputs; and a set of output characteristics of the output signals.

### TECHNICAL FIELD

This disclosure generally relates to audio pre-amplifiers and related systems and methods. More particularly, the disclosure relates to an audio pre-amplifier configured to receive a plurality of distinct inputs and control a plurality of distinct zone outputs.

### BACKGROUND

Many conventional audio pre-amplifiers are limited in capabilities, and namely act only to control signal quality and character (e.g., by boosting signal for output by an amplifier). These conventional pre-amplifiers are not configured to act in switching and/or routing signals for input to output configurations. In other terms, theses conventional pre-amplifiers are limited in their ability to simultaneously control several audio inputs.

### SUMMARY

All examples and features mentioned below can be combined in any technically possible way.

Various aspects include audio pre-amplifiers for controlling zoned audio outputs, both in terms of switching and in controlling output characteristics of the signals.

In some particular aspects, an audio pre-amplifier includes: a plurality of distinct inputs for receiving audio input signals; a plurality of distinct zone outputs for providing output signals according to zoned audio outputs; and at least one processor configured to control: switching the plurality of distinct inputs relative to the plurality of distinct zoned outputs; and a set of output characteristics of the output signals.

Implementations may include one of the following features, or any combination thereof.

In some cases, the set of output characteristics includes one or more of: tone, equalization, band selection (e.g., including limitation), output level, balance between channels (e.g., left and right), subwoofer channels, and crossover frequency selection (e.g., configuring high pass and/or low pass filters for channel selection such as subwoofer channel selection.

In certain aspects, the distinct zoned outputs are provided to a separate audio power amplifier connected to a set of speakers.

In particular implementations, the set of output characteristics impact the quality and character of the output signals.

In some cases, the processor is configured to enable grouping of a set of up to four additional audio pre-amplifiers.

In some aspects, the processor is configured to act as a primary controller for the set of up to four additional audio pre-amplifiers.

In certain cases, each input is configured to receive a two-channel input signal, e.g., a stereo input signal.

In some cases, the two-channel input signal includes both a left input channel and a right input channel.

In particular aspects, each zoned audio output enables three-channel output.

In some cases, the three-channel output includes a left channel output, a right channel output, and a subwoofer (SW) output.

In certain aspects, the plurality of distinct inputs includes up to nine inputs. In one example, the nine inputs include four auxiliary inputs, two coaxial inputs, two optical inputs, and one Bluetooth (BT) input.

In some cases, the zoned audio outputs include up to six distinct audio zones.

In particular aspects, the processor is configured to perform a multi-zone control function in response to receiving a control command to adjust a first zoned output.

In certain cases, the multi-zone control function includes adjusting at least one of: audio routing, volume control for two or more zones, or volume control for groups of zones.

In some aspects, each zoned output is defined by a physical space or a set of speakers for audio output in a physical space. In particular examples, physical spaces are defined as different rooms within an environment (e.g., home, office, etc.) different floors within an environment, indoor or outdoor environments, and/or room types (e.g., bedrooms, party spaces, etc.).

In certain cases, the processor is further configured to control audio output in one or more groups of zoned outputs.

In some implementations, a zoned output can be part of multiple groups concurrently (or, simultaneously).

In certain aspects, any input can be directed to one or more of the zoned outputs.

In some cases, the output signals are configurable to send as an input to: a distinct pre-amplifier in a daisy chain configuration, and an input to a power amplifier or speaker in a direct output configuration.

In certain cases, the processor is configured to detect an additional audio pre-amplifier on a common network connection.

In particular aspects, switching and the set of audio output characteristics are controllable using a connected smart device with a software application.

In some cases, the processor is configured to adjust one or more zone-based controls for a plurality of groups of zones.

In certain aspects, at least one zoned output is part of at least two distinct groups of zones, and wherein the at least one processor is configured to: receive a group-based level adjustment command; and mitigate adjustment in a level of the output signals in the at least one zone that is part of the at least two distinct groups of zones.

In some implementations, the adjustment is mitigated to avoid a sudden change in output level in the at least one zone.

Some aspects include a method of controlling the audio pre-amplifier.

Two or more features described in this disclosure, including those described in this summary section, may be combined to form implementations not specifically described herein.

The details of one or more implementations are set forth in the accompanying drawings and the description below. Other features, objects and advantages will be apparent from the description and drawings, and from the claims.

### DESCRIPTION OF THE DRAWINGS

FIG. 1 is a schematic depiction of an audio pre-amplifier according to various implementations.

FIG. 2 is a schematic rear view of an audio pre-amplifier illustrating device connections according to various implementations.

FIG. 3 is a schematic system diagram showing an audio pre-amplifier coupled with a power amplifier and speakers according to various implementations.

FIG. 4 is a schematic view of an environment including a plurality of audio pre-amplifiers for controlling zoned outputs according to various implementations.

FIG. 5 is a flow diagram illustrating processes in controlling group-based adjustment according to various implementations.

It is noted that the drawings of the various implementations are not necessarily to scale. The drawings are intended to depict only typical aspects of the disclosure, and therefore should not be considered as limiting the scope of the invention. In the drawings, like numbering represents like elements between the drawings.

### DETAILED DESCRIPTION

As noted herein, various aspects of the disclosure generally relate to audio pre-amplifiers, related systems, and related control methods. These audio pre-amplifiers can enhance the user experience and/or the installer experience in configuring and/or reconfiguring an audio system. In particular cases, implementations include audio pre-amplifiers that are configured to receive a plurality of distinct inputs, and control output audio in zones in terms of both switching and output characteristics. Additional implementations include controlling groups of zoned outputs.

Commonly labeled components in the FIGURES are considered to be substantially equivalent components for the purposes of illustration, and redundant discussion of those components is omitted for clarity. Numerical ranges and values described according to various implementations are merely examples of such ranges and values, and are not intended to be limiting of those implementations. In some cases, the term “approximately” is used to modify values, and in these cases, can refer to that value +/− a margin of error, such as a measurement error.

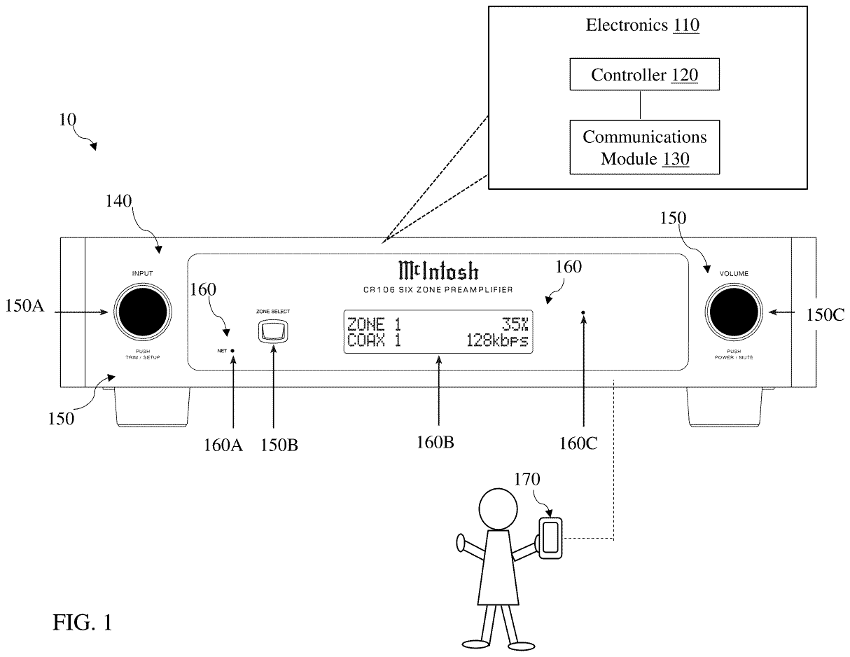

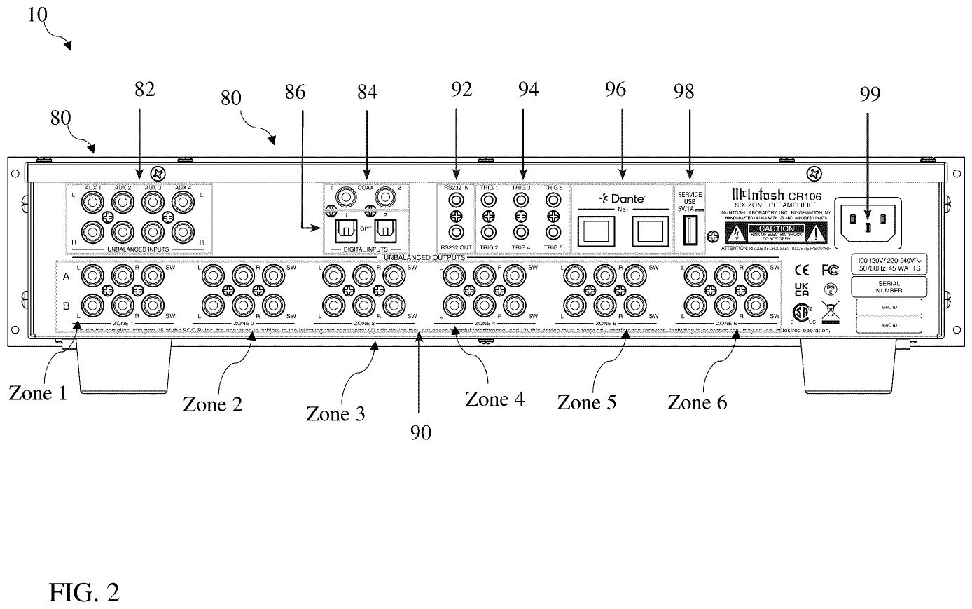

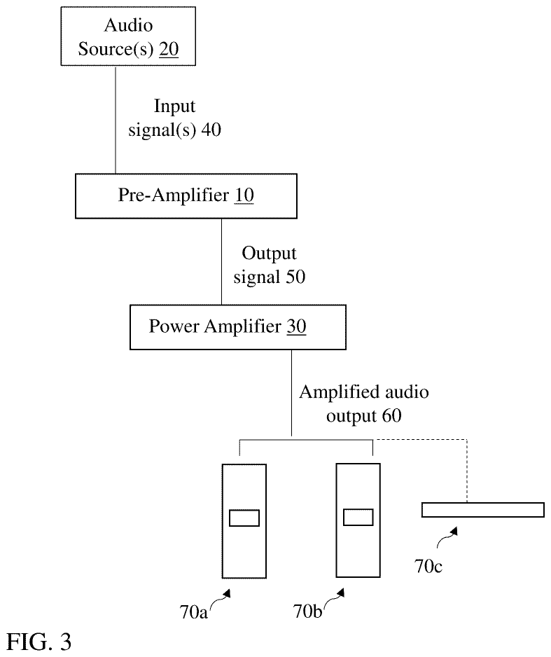

FIG. 1 is a schematic front view, and FIG. 2 a schematic rear view, of an illustrative audio pre-amplifier (or simply, pre-amplifier) 10 according to various implementations. FIG. 3 shows the pre-amplifier 10 connected with an audio source 20 and a separate audio (power) amplifier 30. FIGS. 1-3 are referred to simultaneously.

The pre-amplifier 10 can be configured to receive audio input signals 40 from the source 20, and provide an (audio) output signal 50 to the power amplifier 30. The power amplifier 30 amplifies the output signal 50 from the pre-amplifier 10 to provide an amplified audio output 60 to one or more speakers 70 (e.g., via hard-wired connection(s)). As described herein, the pre-amplifier 10 is configured to control zoned audio outputs, both in terms of switching and in controlling output characteristics of the signals.

As illustrated in FIG. 2 and described herein, the pre-amplifier 10 can include a plurality of distinct inputs 80 for receiving audio input signals, e.g., from a plurality of audio sources. In certain cases, each input 80 is configured to receive a two-channel input signal, e.g., a stereo input signal. In some examples, the two-channel input signal includes both a left input channel and a right input channel. In certain non-limiting examples, the inputs 80 include up to nine inputs. In one such example, the inputs include four (4) auxiliary inputs 82, two (2) coaxial inputs 84, two (2) optical inputs 86, and one (1) Bluetooth (BT) input (not shown).

With continuing reference to FIG. 2, the pre-amplifier 10 can also include a plurality of distinct zone outputs 90 for providing output signal(s) 50 according to zoned audio outputs (Zones 1, 2, 3, 4, etc.). As described herein, the output signals 50 are configurable to send as an input to: a distinct pre-amplifier 10 in a daisy chain configuration, and an input to a power amplifier 30 or speaker 70 in a direct output configuration. FIG. 2 also shows connections on pre-amplifier 10 including a serial communication (e.g., RS232 connector) jack 92, a trigger (TRIG) connector 94 (e.g., for communicating, such as sending On/Off commands with other audio system components such as power amplifier(s) 30), local area network (LAN) connectors 96 such as Dante connectors, a USB (e.g., service) connector 98, and a power connector 99.

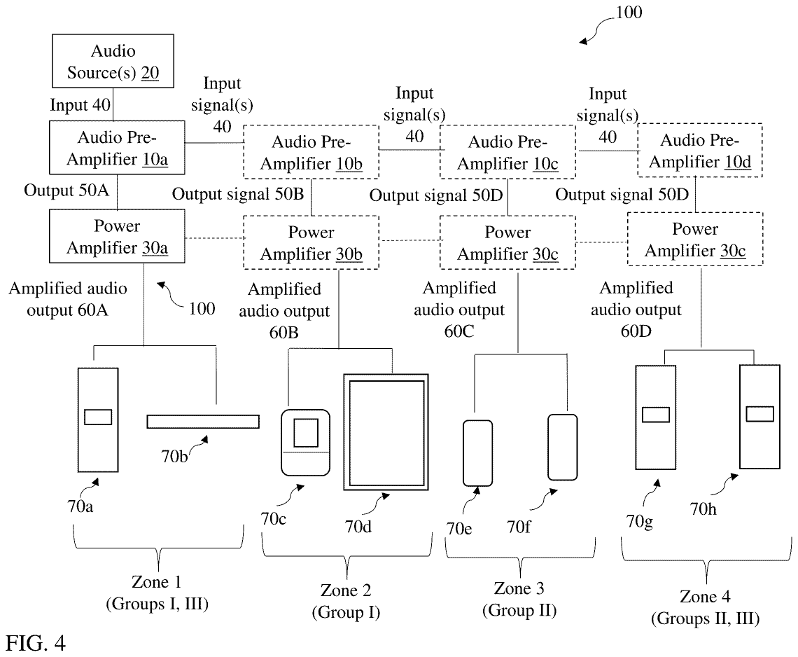

In a particular example, as depicted schematically in environment 100 in FIG. 4, pre-amplifier 10 can be configured to provide zone outputs 90 to two, three, four, five, or more Zones. In one example, the pre-amplifier 10 can be configured to provide zone outputs 90 to up to size (6) Zones (FIG. 2). As noted herein, each zone output 90 can be connected with one or more power amplifiers 30 for providing an amplified output 60 to one or more Zones. In other cases, multiple zone outputs 90 can be routed through the same power amplifier 30 (e.g., a power amplifier 30 with multiple power amplifier channels) for providing an amplified output 60 to one or more Zones. In particular aspects, as shown in FIG. 2, each zone output 90 enables three-channel output; for example, including a left channel (L) output, a right channel (R) output, and a subwoofer (SW) output.

Returning to FIG. 1, the pre-amplifier 10 can also include electronics 110 (e.g., within its housing) including a controller 120 (which may include one or more processors such as digital signal processors (DSPs) and/or microprocessors) that is configured to control at least: a) switching the plurality of distinct inputs 40 relative to the plurality of distinct zoned outputs 90 (e.g., Zones 1, 2, 3, etc.); and b) a set of output characteristics of the output signals 50. In particular implementations, the set of output characteristics impact the quality and character of the output signals. For example, the set of output characteristics can include one or more of: tone, equalization, band selection (e.g., including limitation), output level, balance between channels (e.g., left and right), subwoofer channels, and crossover frequency selection (e.g., configuring high pass and/or low pass filters for channel selection such as subwoofer channel selection). Electronics 110 can include a communication module 130 connected with controller 120, along with other circuity and modules not depicted, e.g., audio switches, analog-to-digital converters (ADC) and digital to analog convertors (DAC), ethernet modules, interface modules, switches, buffer modules, etc.

In some cases, controller 120 can include one or more processors, memory, communications pathways between components, and/or one or more logic engines for executing program code. In certain examples, the controller 120 includes a microcontroller or processor having a digital signal processor (DSP), such that analog signals are converted to digital format by analog to digital converters. Controller 120 can be coupled with other components in the pre-amplifier 10 (e.g., communications module 70 and/or processors) via any conventional wireless and/or hardwired connection which allows controller 120 to send/receive signals to/from those components and control operation thereof. The communications module 130 can include a wireless transceiver for communicating with other devices in the environment. In other cases, the communications module 130 can communicate with other devices using any conventional hard-wired connection and/or additional communications protocols. In some cases, communications protocol(s) can include local area wireless network communication protocol (e.g., a wireless fidelity (Wi-Fi) protocol using a wireless local area network (WLAN)), a communication protocol such as IEEE 802.11 b/g or 802.11 ac, a cellular network-based protocol (e.g., third, fourth or fifth generation (3G, 4G, 5G cellular networks) or one of a plurality of internet-of-things (IoT) protocols, such as: Bluetooth, BLE Bluetooth, ZigBee (mesh LAN), Airplay (and variations), Chromecast (and variations), Z-wave (sub-GHz mesh network), 6LoWPAN (a lightweight IP protocol), LTE protocols, RFID, ultrasonic audio protocols, etc. In additional cases, the communications module 130 can enable the pre-amplifier 10 to communicate with a remote server, such as a cloud-based server running an application for managing pre-amplifier functions. In certain implementations, as noted herein, the communications module is configured to communicate with other devices and/or a network over both a local area wireless network communication protocol (e.g., Wi-Fi communication protocol) and at least one additional communication protocol (e.g., a direct device communication protocol, for example, via an ethernet connection protocol such as Dante).

FIG. 1 shows an interface 140 on the pre-amplifier 10 for enabling a user to control operation of the device. The interface 140 can include various input controls 150, along with (status and other) indicators 160 about device operation. For example, input control 150A (e.g., knob, dial and/or push-button) can be used to enable input selection such as selecting one of numerous inputs 80 for pre-amplification control. Input control 150A can also allow for editing the list of inputs 80 available for selection and/or grouping. Input control 150B can include a zone select function, and may include a button, toggle, etc. for cycling between a set of available zone contexts. Input control 150C can include a button, toggle, dial, etc., includes an output control that can enable volume control (including muting), power on/off control, setup/trim controls, etc. Indicator 160A includes a network indicator showing device network connection status. Indicator 160B includes a visual display including information such as input selection, zone outputs, etc., Indicator 160C includes a status indicator such as a connection indicator (e.g., AC connection and/or current power status, on v. off). Additional interface functions can include switching and the set of audio output characteristics, as described herein. In various implementations, interface functions can be controlled via a connected device 170, e.g., a remote controller and/or smart device running a software application.

In particular aspects, with reference to FIG. 4, the controller 120 is configured to perform a multi-zone control function in response to receiving a control command (e.g., via one or more interfaces) to adjust a first zoned output (e.g., Zone 1). In certain cases, the multi-zone control function includes adjusting at least one of: audio routing, volume control for two or more zones (e.g., Zone 1, Zone 2, etc.), or volume control for groups of zones (e.g., Zone 2, Zone 3, etc.).

As illustrated in FIG. 4, in some aspects, each zoned output (e.g., Zones 1, 2, 3, etc.) is defined by a physical space (e.g., room, walls, partitions, etc.) or a set of speakers (e.g., speakers 70A and 70B, speakers 70C-E, speaker 70F, etc.) for audio output in a physical space. In particular examples, physical spaces are defined as different rooms within an environment (e.g., home, office, etc.), different floors within an environment (e.g., upstairs, downstairs, basement, terrace level, roof deck), indoor or outdoor environments (e.g., sunroom v. patio, bedroom v. balcony, etc.), and/or room types (e.g., kitchen, bedrooms, party spaces, etc.). In one example, Zone 1 is a kitchen space, Zone 4 is a patio space off the kitchen, Zone 2 is a living room space, and Zone 3 a library.

In addition to enabling zone-based control, the controller 120 is also configured to control audio output in one or more groups of zoned outputs (e.g., Groups I, II, III). Groups are defined as including two or more zones (e.g., Group I=Zones 1+2, Group II =Zones 3+4, Group III=Zones 1+4, etc.). In various cases, a zoned output (e.g., Zone 1, Zone 4) can be part of multiple groups concurrently (or, simultaneously). Further, in certain aspects, any input 80 can be directed to one or more of the zoned outputs (e.g., Zones 1, 2, 3, 4, 5, 6, etc.).

In some cases, the controller 120 is configured to adjust one or more zone-based controls for a plurality of groups of zones. For example, in response to receiving a command to change at least one zone-based function (e.g., via interface(s)), the controller 120 can be configured to adjust a control function for all groups that include that zone.

In certain additional aspects, at least one zoned output (e.g., Zone 1) is part of at least two distinct groups of zones (e.g., Group I and Group III). In this example, the controller 120 is configured to: a) receive a group-based level adjustment command (e.g., lower volume in Group I); and b) mitigate adjustment in a level of the output signals in the zone (or zones) that is part of the at least two distinct groups of zones. In this example, the controller 120 mitigates adjustment in level of Zones 1 and 4 because each of those Zones is shared between two groups. In some implementations, the adjustment is mitigated to avoid a sudden change in output level in the (shared, or common) zone, e.g., Zone 1 or Zone 4.

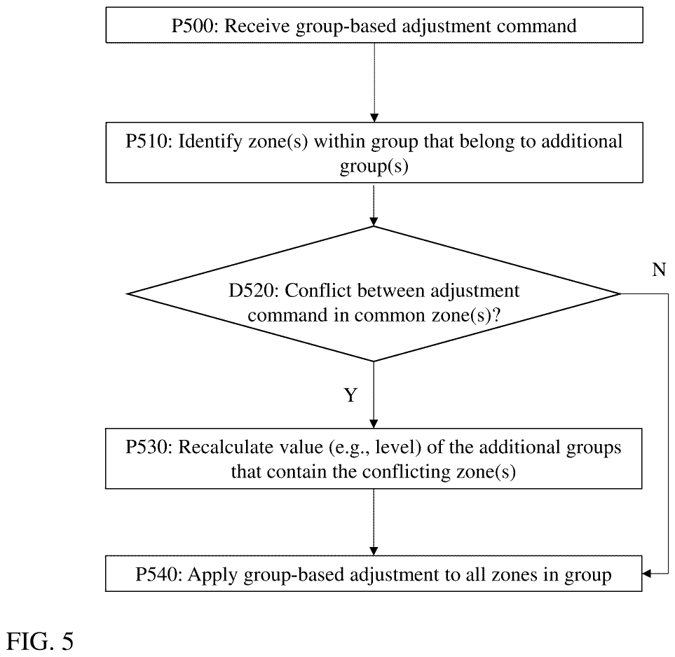

FIG. 5 is a flow diagram illustrating processes in an example implementation of mitigating adjustment in output signals to zone(s) that are part of distinct zone groups. It is understood that the process can be performed by controller(s) 120 in various implementations. Processes in this example method can include:
P500: receive a group-based adjustment command (e.g., a level adjustment command such as increasing the volume in a first group such as Group I). In some cases, the group-based adjustment command is received at the controller 120 via an interface, e.g., at interface 140 and/or an interface at connected device 170;
P510: identify zone(s) with in the group (e.g., Group I) that belong to additional group(s), e.g., Zone 1;
D520: determine whether a conflict exists between the adjustment command in common zones. For example, does a conflict exist between the adjustment command for Group I (including Zones 1 and 2) and Group III (including Zones 1 and 4)?
P540: if no conflict exists (N to D520), the process includes applying group-based adjustments (e.g., as specified in the command in P500) to all zones in the group (e.g., for Group I, Zones 1 and 2); and
P530: if a conflict does exist (Y to D520) between groups with a common zone (e.g., Groups I and III, with Zone 1 in common), the controller 120 recalculates the value representing the output characteristic (e.g., the abstract value representing the output characteristic such as level) for the additional group that contains the conflicting zone (e.g., Group III).

After recalculating the value of the additional groups (P530), the process can continue to apply the group-based adjustments to all zones in the group (P540).

In this approach, mitigation can be effective because subsequent adjustment of the output characteristic (e.g., level) in the additional member group (e.g., Group III), e.g., via a direct control command, will not cause a sudden change in member zones within the group. In some cases, this is because group output control primarily uses cached offset information to apply changes to member zones.

It is understood that any adjustment command for a zone in multiple groups can be evaluated according to the approach outlined in FIG. 5. For example, in addition to level, equalization, tone, band selection, etc., can be controlled in a multi-group approach as outlined herein.

In further implementations, as noted herein, groups (e.g., Groups I, II, III, etc.) can share common zones (e.g., Zones 1, 2, 3, etc.). In many cases, corresponding output levels for a group represent the true output to a zone. In such cases, mitigation can be performed to avoid a sudden jump or drop in output level (volume) based on group-level change. According to various implementations, the controller 120 controls displaying the percent output for a group and/or zone, e.g., on an interface. In certain aspects, the output for a group and/or zone can be displayed as either increments or steps based on user perception, e.g., in a stepwise or linear function.

In various implementations, as illustrated schematically in FIG. 4, the controller 120 is configured to enable grouping of a set of up to four additional audio pre-amplifiers. In the example depicted, four distinct pre-amplifiers 10a, 10b, 10c, 10d, are shown, but it is understood that a fifth pre-amplifier can be connected in some cases. In some of these cases, the controller 120 (at pre-amplifier 10a) is configured to act as a primary controller for the set of additional audio pre-amplifiers (e.g., audio pre-amplifiers 10b, 10c, 10d, etc.). In particular aspects, the controller 120 (at pre-amplifier 10a) is configured to detect an additional audio pre-amplifier (e.g., pre-amplifier 10b, 10c, 10d, etc.) on a common network connection. It is understood that the depiction in FIG. 4 of multiple pre-amplifiers 10b, 10c, 10d, etc., is optional, and that the output signals 60B, 60C, 60D, etc., can be controlled by a single pre-amplifier 10a (and corresponding power amplifier 30a) according to various implementations.

It is further understood that various functions of pre-amplifiers can be determined (e.g., predefined or otherwise configured) at an installation phase, e.g., by an installing user such as a professional audio technician.

As noted herein, relative to conventional pre-amplifiers, the disclosed audio pre-amplifiers can enhance the user experience and/or the installer experience in configuring and/or reconfiguring an audio system. These devices and related systems and approaches have the technical effect of allowing a plurality of distinct inputs, and controlling output audio in zones in terms of both switching and output characteristics. Further, the disclosed devices and systems enable controlling inputs and outputs from distinct physical spaces. For example, the devices and systems do not require that inputs and outputs be co-located, because multiple pre-amplifiers can be interlinked (e.g., over a network connection) from different physical spaces.

Some aspects include a method of controlling the audio pre-amplifier 10 according to approaches described herein, e.g., via software and/or programmable hardware components.

The functionality described herein, or portions thereof, and its various modifications (hereinafter “the functions”) can be implemented, at least in part, via a computer program product, e.g., a computer program tangibly embodied in an information carrier, such as one or more non-transitory machine-readable media, for execution by, or to control the operation of, one or more data processing apparatus, e.g., a programmable processor, a computer, multiple computers, and/or programmable logic components.

A computer program can be written in any form of programming language, including compiled or interpreted languages, and it can be deployed in any form, including as a stand-alone program or as a module, component, subroutine, or other unit suitable for use in a computing environment. A computer program can be deployed to be executed on one computer or on multiple computers at one site or distributed across multiple sites and interconnected by a network.

Actions associated with implementing all or part of the functions can be performed by one or more programmable processors executing one or more computer programs to perform the functions of the calibration process. All or part of the functions can be implemented as, special purpose logic circuitry, e.g., an FPGA and/or an ASIC (application-specific integrated circuit). Processors suitable for the execution of a computer program include, by way of example, both general and special purpose microprocessors, and any one or more processors of any kind of digital computer. Generally, a processor will receive instructions and data from a read-only memory or a random access memory or both. Components of a computer include a processor for executing instructions and one or more memory devices for storing instructions and data.

In various implementations, electronic components described as being “coupled” can be linked via conventional hard-wired and/or wireless means such that these electronic components can communicate data with one another. Additionally, sub-components within a given component can be considered to be linked via conventional pathways, which may not necessarily be illustrated.

Other embodiments not specifically described herein are also within the scope of the following claims. Elements of different implementations described herein may be combined to form other embodiments not specifically set forth above. Elements may be left out of the structures described herein without adversely affecting their operation. Furthermore, various separate elements may be combined into one or more individual elements to perform the functions described herein.

We claim:

1. An audio pre-amplifier comprising:
a plurality of distinct inputs for receiving audio input signals;
a plurality of distinct zone outputs for providing output signals according to zoned audio outputs; and
at least one processor configured to control:
switching the plurality of distinct inputs relative to the plurality of distinct zoned outputs; and
a set of output characteristics of the output signals.

2. The audio pre-amplifier of claim 1, wherein the set of output characteristics includes one or more of:
tone, equalization, band selection, output level, balance between channels, subwoofer channels, and crossover frequency selection.

3. The audio pre-amplifier of claim 1, wherein the distinct zoned outputs are provided to a separate audio power amplifier connected to a set of speakers.

4. The audio pre-amplifier of claim 1, wherein the set of output characteristics impact the quality and character of the output signals.

5. The audio pre-amplifier of claim 1, wherein the at least one processor is configured to:
enable grouping of a set of up to four additional audio pre-amplifiers, and
act as a primary controller for the set of up to four additional audio pre-amplifiers.

6. The audio pre-amplifier of claim 1, wherein each input is configured to receive a two-channel input signal, wherein the two-channel input signal includes both a left input channel and a right input channel.

7. The audio pre-amplifier of claim 1, wherein each zoned audio output enables three-channel output, wherein the three-channel output includes a left channel output, a right channel output, and a subwoofer (SW) output.

8. The audio pre-amplifier of claim 1, wherein the plurality of distinct inputs includes up to nine inputs.

9. The audio pre-amplifier of claim 1, wherein the zoned audio outputs include up to six distinct audio zones.

10. The audio pre-amplifier of claim 1, wherein the at least one processor is configured to perform a multi-zone control function in response to receiving a control command to adjust a first zoned output,
wherein the multi-zone control function includes adjusting at least one of: audio routing, volume control for two or more zones, or volume control for groups of zones.

11. The audio pre-amplifier of claim 1, wherein each zoned output is defined by a physical space or a set of speakers for audio output in a physical space.

12. The audio pre-amplifier of claim 1, wherein the at least one processor is further configured to control audio output in one or more groups of zoned outputs, wherein a zoned output can be part of multiple groups concurrently.

13. The audio pre-amplifier of claim 1, wherein any input can be directed to one or more of the zoned outputs simultaneously.

14. The audio pre-amplifier of claim 1, wherein the output signals are configurable to send as an input to:
a distinct pre-amplifier in a daisy chain configuration, and
an input to a power amplifier or speaker in a direct output configuration.

15. The audio pre-amplifier of claim 1, wherein the at least one processor is configured to detect an additional audio pre-amplifier on a common network connection.

16. The audio pre-amplifier of claim 1, wherein switching and the set of audio output characteristics are controllable using a connected smart device with a software application.

17. The audio pre-amplifier of claim 1, wherein the at least one processor is configured to adjust one or more zone-based controls for a plurality of groups of zones.

18. The audio pre-amplifier of claim 17, wherein at least one zoned output is part of at least two distinct groups of zones, and wherein the at least one processor is configured to:
receive a group-based level adjustment command; and
mitigate adjustment in a level of the output signals in the at least one zone that is part of the at least two distinct groups of zones.

19. The audio pre-amplifier of claim 18, wherein the adjustment is mitigated to avoid a sudden change in output level in the at least one zone.

20. A method of controlling the audio pre-amplifier of claim 1.
